(19) United States
(12) Patent Application Publication
(10) Pub. No.: US 2005/0045469 A1
(43) Pub. Date: Mar. 3, 2005

(54) Titanium foil metallization product and process

(75) Inventors: Brad M. Fye, Arnold, MD (US); Thomas A. Andersen, Catonsville, MD (US)

Correspondence Address: ROTHWELL, FIGG, ERNST & MANBECK, P.C., 1425 K STREET, N.W., SUITE 800, WASHINGTON, DC, 20005, US

(73) Assignee: Northrop Grumman Corporation, Los Angeles, CA (US)

(21) Appl. No.: 10/927,462

(22) Filed: Aug. 27, 2004

Related U.S. Application Data
(60) Provisional application No. 60/498,650, filed on Aug. 29, 2003.

(51) Int. Cl. C23C 14/00

(52) U.S. Cl. 204/192.15; 204/192.12

(57) ABSTRACT

According to some preferred embodiments, a physical vacuum deposition process for titanium foil can include: sputter etching one side of the titanium foil for about, e.g., 5 to 20 minutes; sputter depositing Titanium or a Titanium-Tungsten alloy; sputter depositing a low stress nickel; sputter depositing gold; reversing the foil and repeating these steps.

The present application claims priority to U.S. Provisional Application Ser. No. 60/498,650, entitled Titanium Foil Metallization Product and Process, filed on Aug. 29, 2003, the entire disclosure of which is incorporated herein by reference.

### FIELD OF THE INVENTION

The present invention relates generally to, among other things, titanium foil metallization products and processes, and certain preferred embodiments relate, more particularly, to titanium foil metallization products and processes for protecting transducers, such as, in some illustrative embodiments, underwater ultrasonic transducers.

### PREFERRED APPLICATIONS

While some preferred embodiments of the present invention can be used to improve transducers and, especially, underwater ultrasonic transducers, aspects of the present invention can be employed in a variety of applications (as described below).

A transducer is any device that translates energy from one form into another (e.g., electrical to mechanical, magnetic to mechanical, magnetic to electrical, etc.) . For example, transducers can be used to convert acoustic pressure waves into electrical energy. A good overview on the subject of transducers including a history of the devices is given by Hunt, Electroacoustics, published by Wiley, 1954.

As indicated, in some instances, transducers can be employed in underwater environments, such as, e.g., sonar transducers that can, for example, convert sound waves to electrical energy. Some preferred embodiments of the present invention can be employed in ultrasonic underwater transducers. Illustrative transducers can be seen, e.g., in U.S. Pat. No. 4,271,707 (listed upon issuance as assigned to Northrop Corporation), the entire disclosure of which is incorporated herein by reference, which shows:
In FIG. 1, a scanning head 1 of an ultrasonic inspection system contains a linear array of 32, for example, piezo-electric transducers 2 positioned substantially even with an outer surface of the head 1 which is physically moved adjacent to one surface of an aircraft vertical stabilizer 4, for example, being inspected. As will be understood, the inspection process may be carried out under water or other liquid as a transmission medium for the ultrasonic waves. In some instances, the transducers 2 may physically touch the inspected material.

Existing transducers, such as, e.g., underwater transducers have limited ability to withstand environmental conditions, such as, e.g., underwater conditions for long periods of time.

Existing methods for protecting underwater transducers and/or the like have limitations. There is a need for systems and methods that can overcome the above and/or other problems with existing systems. In some preferred embodiments of the invention, transducers and/or the like can be protected by the implementation of new and improved protective coatings.

### COATING SUBSTRATES

There are a number of ways to coat a layer on a substrate. In general, films can be deposited using methods with or without vacuum technology. Current vacuum deposition techniques can be classified, e.g., into two categories: physical vapor deposition (such as, e.g., sputtering; etc.) and chemical vapor deposition. Typically, both of these categories involve the use of vacuum systems. See, e.g., U.S. Published patent application No. 20030103256A1 published on Jun. 5, 2003 (noting “physical vacuum deposition methods, such as vapor deposition, sputtering, Chemical Vapor Deposition (CVD) (David A. Glocker, Ismat Shah (Ed.) Handbook of Thin Film Process Technologie, Institute of Physics Publishing, Bristol and Philadelphia 1995).”)

A. Sputter Coating:

Sputter coating typical does not need as high temperatures as in metallizing processes. During sputtering, high energy chemically inert ions from a gas plasma bombard a target material to be deposited. This releases atoms in the form of a vapor stream, which condenses and deposits onto a substrate. The deposit adheres to the film surface. There are a large number of sputtering system manufacturers. See, e.g., list of manufacturers identified by Semicore Equipment, Inc., at
http://www.semicore.com/systems_tech.htm (Identifying “Applied Materials, Leybold, Balzers, MRC, CHA Industries, Matrix, Circuit Process, Apparatus (CPA), Nordiko, Commonwealth, Scientific, Oxford Instruments, Comptech, Perkin Elmer, CVC Products, Plasma Technologies, Davis @ Wilder (D&W), Plasma-Therm, Denton Vacuum, SEGI sputtering systems, Edwards, Technics, Ion Tech, Tegal, Branson, Temescal/BOC, Kurt J Lesker, Tokyo Electron (TEL), Lam Research, Varian, Veeco”).

In sputter deposition, a planar source can enable material to be sputtered from substantially all points on a target with material arriving at a substrate from a wide range of angles. In sputtering, control of film characteristics is available by the balancing of the sputtering parameters of pressure, deposition rate and target material.

A document posted on the Chung Hua University Web Site at http://www.me.chu.edu.tw/˜jmlin/Chap13.ppt indicates that “adhesion and surface cleanliness can be increased by grounding the wafer holder and sputtering the wafer surface for a brief time prior to the deposition. In this mode, the sputter system is functioning as an ion-etch (sputter etch, reverse-sputter) machine.”

B. Ion Vapor Deposition:

Ion Vapor Deposition can include, e.g., processes for applying a protective coating to a material or part in an evacuated chamber with a d-c glow discharge. The evaporated plating material is ionized and forms an adherent coating.

There is an ongoing need for new systems and methods that can improve upon existing coating methodologies and/or that can be used advantageously in transducer and/or other environments.

### SUMMARY OF THE INVENTION

Various embodiments of the present invention can significantly improve upon existing systems and methods. In some preferred embodiments of the present invention, one or more of the above and/or other problems with existing systems can be overcome.

1. Transducer Embodiments

Transducer efficiency and sensitivity are often important considerations. Protective devices for transducers preferably do not interfere with their operation. With, for example, wave detecting transducers (such as, e.g., under water ultrasonic transducers), the thickness of a protective foil is preferably small with respect to a wavelength. Additionally, the foil is preferably formed to be very flat and without wrinkles or the like.

2. Deposition Processes

Previously, ion vapor deposition and plating procedures employed had some limitations. The most preferred embodiments involve a substantially total vacuum deposition process that preferably avoids the use of previously contemplated plating processes. Prior procedures were difficult to reproduce in a high rate production environment while meeting stringent quality control standards. Among other things, prior procedures were unable to achieve high life requirements, such as, e.g., a needed 12-year life requirement for sonar transducers.

According to some preferred embodiments, a process to metallize very thin (such as, e.g., between about 0.0005″ and 0.002″ in some embodiments and/or about 0.001″ in some embodiments) titanium foils having a purity of greater than about 99.8% is provided. Among other things, preferred embodiments can be used, e.g., in the manufacture of improved barriers (e.g., water barriers and/or the like). For example, preferred embodiments can be used for creating long-term barriers and/or barriers for underwater use, such as, e.g., for underwater transducers and/or the like.

In some preferred embodiments, metallization process improvements for a total vacuum deposition process are coupled with enhanced deposit adhesion, while enabling manufacturing that at increased reliability, at high rates and/or at low costs. The preferred embodiments can extend the service life of a transducer or the like substantially (such as, e.g., extending underwater transducer life from about 10 years to about 12 years or more in some embodiments).

The above and/or other aspects, features and/or advantages of various embodiments will be further appreciated in view of the following description in conjunction with the accompanying figures. Various embodiments can include and/or exclude different aspects, features and/or advantages. In addition, various embodiments can combine one or more aspect or feature from other embodiments. The descriptions of aspects, features and/or advantages of particular embodiments should not be construed as limiting other embodiments or the claims.

### BRIEF DESCRIPTION OF THE DRAWINGS

The accompanying figures are provided by way of example, without limiting the broad scope of the invention or various other embodiments, wherein:

FIG. 1(A) is a perspective view of an illustrative underwater transducer having a protective foil in accordance with some embodiments described herein;

FIG. 1(B) is a perspective view of an illustrative underwater transducer similar to that shown in FIG. 1(A) without a neoprene or the like boot covering the foil;

FIG. 2 is a diagram demonstrating adhesion difficulties with titanium foils with nickel and gold layers;

FIG. 3 is a diagram demonstrating the presence of carbon and/or oxygen at regions having adhesion difficulties in FIG. 2;

FIG. 4 is a chart illustrating some titanium foil sputter etching results;

FIG. 5 is a graph illustrating sputter etching removal of carbon;

FIG. 6 is a graph illustrating sputter etching removal of oxygen; and

FIG. 7 is a graph illustrating chemical milling removal of carbon and oxygen.

### DETAILED DESCRIPTION OF THE PREFERRED EMBODIMENTS

While the present invention may be embodied in many different forms, a number of illustrative embodiments are described herein with the understanding that the present disclosure is to be considered as providing examples of various principles of the invention and such examples are not intended to limit the invention to preferred embodiments described herein and/or illustrated herein.

Previously, ion vapor deposition and plating procedures had limitations. The preferred embodiments provide a total vacuum deposition process that preferably avoids the use of previously contemplated plating processes. Prior procedures were difficult to reproduce in a high rate production environment while meeting stringent quality control standards. Among other things, prior procedures were unable to achieve high life requirements, such as, e.g., the 12-year life requirements for sonar transducers.

In some preferred embodiments, the vacuum deposition process includes a sputtered metal deposition process. Preferred embodiments have been developed that improve, e.g., the deposition adhesion of over layers of a thin titanium foil (which can be, e.g., in some illustrative embodiments, between about 0.0005 and 0.002 inches thick, or, in other illustrative embodiments, between about 0.00075 and 0.0015 inches thick, or, in other illustrative embodiments about 0.001 inches thick), enabling the production of acceptable water barriers at a high production rate while meeting underwater sonar application requirements.

Illustrative Applications and Environments

In some applications, transducers need to have shielding against environmental conditions, such as, e.g., salt water. Accordingly, salt-water protective coatings can be applied that to establish a substantially impervious shield against water permeation and/or the like.

In addition to having protective qualities, in preferred applications, these coatings also need to be substantially acoustically transparent (e.g., to maintain frequency amplitude performance and phase accuracy at the element). For example, these coatings are preferably of a small thickness due to this requirement. In addition, the coatings may need to be generally flexible, to be generally lightweight and/or to be generally bondable to provide reliable performance. In addition, the coatings preferably have some or all of these features at various depths beneath a top surface of a body of water and/or at various water temperatures.

In some preferred environments (such as, e.g., with underwater transducers), a life expectancy of about 12 years or more of continuous use may be required (and, in some environments, continuous use without servicing).

In some preferred embodiments, a corrosion resistant titanium foil (having a thickness of about 0.001 inches in some illustrative embodiments) is covered with a protective gold plated finish in a unique manner to provide a suitable water barrier for an underwater transducer.

Typically, finishing processing for titanium includes some of the most difficult cleaning and plating procedures known which precluded this material from proper surface preparation while maintaining the flatness requirement of the foil. Some difficulties originate from a thin, naturally forming, oxide film that is often difficult to remove and reforms quickly when a cleaned surface is exposed to, e.g., water or air.

As a result, adherent electro-deposited coatings have been obtained by replacing the oxide film with an alternate coating, etching the titanium to create a mechanical keying between the titanium substrate and plated deposit, or heating the plated titanium to allow inter-diffusion between the substrate and the plated deposit. Chemical processes that permit electro-deposition onto titanium are typically hazardous, expensive and/or difficult to control. Typical hazards include titanium cleaners, surface activators and/or deoxidizers. Other common hazards include concentrated hydrochloric, nitric and/or hydrofluoric acid mixtures operated at elevated temperatures and often-requiring equipment with current (DC) reversing capability. Major environmental problems with waste disposal, ventilation, and chemical logistics greatly increase the risks of titanium electro-deposition processes.

The preferred embodiments can overcome problems of existing methods and can enable the deposition of nickel and gold onto high purity titanium foils (with, e.g., greater than about 99.8% titanium) employing unique total vacuum deposition methodologies.

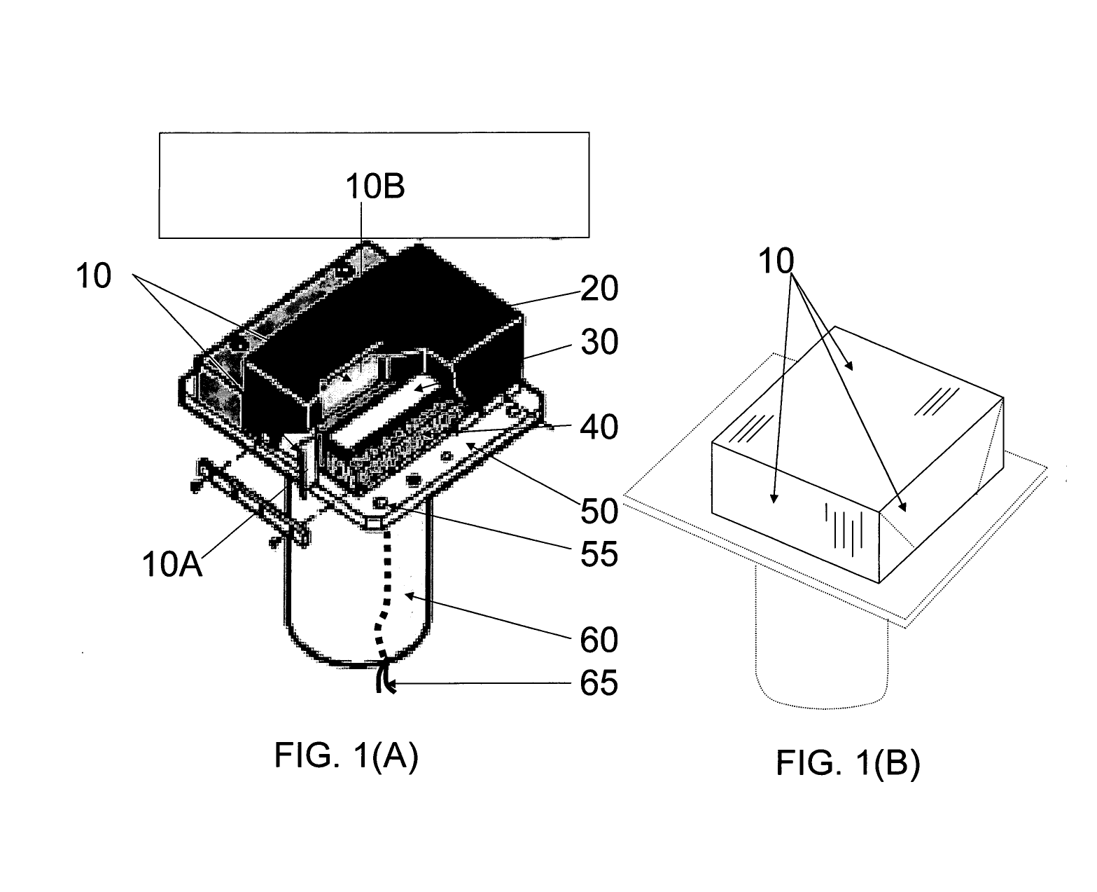

FIG. 1(A) shows one illustrative embodiment pertaining to an underwater transducer cover (e.g., a salt-water exposed transducer cover) folded into a position to seal electronic components. In this illustrative embodiment, a nickel and gold metallized titanium foil is labelled at 10. As shown in FIG. 1(A), the underwater transducer preferably includes, inter alia, an elastomeric (e.g., neoprene or rubber) boot 20 (e.g., covering). Among other things, the boot 20 can help to protect the transducer from water penetration and from external objects. For reference, FIG. 1(B) is a perspective view of an illustrative underwater transducer similar to that shown in FIG. 1(A) without a neoprene or the like boot covering the foil.

In some preferred embodiments, the titanium foil 10 surrounds substantially the entire or the entire exterior of the components of the transducer (such as, e.g., shown in FIG. 1(B)) and the boot 20 surrounds substantially the entire or the entire exterior of the titanium foil 10. In this regard, FIG. 1(A) shows the titanium foil at least partly removed and pealed-outward at points 10A and 10B for explanatory purposes only; however, in preferred embodiments, the titanium foil will surround the transducer components substantially as shown in FIG. 1(B). In some embodiments, the transducer components beneath the titanium foil may include, e.g., a piezoelectric element 30 (such as, by way of example, a piezoelectric rubber (PZR) element in some preferred embodiments), and an acoustic baffle 40. As shown, the transducer may include, e.g., a mounting plate 50 having mounting holes 55 for mounting the same upon a support (not shown), such as, e.g., a support bracket or the like. As shown, the rear side can include a bottle or cylinder 60 for containing electronic wiring 65 and the like for connection to external power sources, for transmission of signals and the like.

In some illustrative embodiments, a sound transducer such as, e.g., shown can be used in underwater environments, such as, e.g., mounted upon fixed objects, floating objects, movable objects, such as, e.g., a hull of a watercraft, such as, e.g., a boat, a ship, a submarine and/or other watercraft.

Description of the Preferred Process

In some preferred embodiments, a novel process is used to apply nickel and gold deposits to both sides of a titanium foil sheet.

In some preferred embodiments, in order to create the foil, vacuum sputter deposition equipment is preferably used that is capable of sputtering one or more titanium foil(s) (which can be in some illustrative and non-limiting embodiments about 5 to 20 inches wide in two dimensions, or in some preferred embodiments about 10 to 15 inches wide in two dimensions, by about a few mil thick, or in some preferred embodiments about 1 mil [0.001 inches] thick or less) with about 100 microinches (0.0001 inches) of nickel followed by about 100 microinches of gold that can pass the adhesion bend test as listed in the ASTM standard number ASTM B488-01 entitled “Standard Specification for Electrodeposited Coatings of Gold for Engineering Uses.” See http://www.ASTM.org.

In some illustrative embodiments, the physical vacuum deposition preferably takes place inside a high. In some preferred embodiments, the foil is turned over while in the vacuum so as to apply the process to both sides of the foil.

In preferred embodiments, a novel physical vacuum deposition (PVD) process (e.g., including a sputter deposition process) is used that provides nickel and gold deposition onto titanium foil in an economical and safe manner. Any appropriate sputtering devices could be employed, such as, e.g., magnetron sputtering devices, diode sputtering devices (e.g., without magnetron or magnetic enhancement), etc.

Obtaining a metallurgical bond between the titanium foil and subsequent metal layers can be a roadblock to successful operation and corrosion protection of an electronic transducer element or the like. The initial bond between a titanium substrate and an under-plate (e.g., which may be about 100 microinches in some embodiments) is dependent upon optimum cleanliness of the titanium surface at the time of metallization. For successful initial metallization, clean titanium surfaces should be established.

Cleaning the titanium surface (e.g., using aqueous and/or non-aqueous cleaners) followed by a vacuum reverse sputter etch is used for deposit adhesion. Vacuum reverse sputter etching can include, e.g., some mechanism of changing the polarity from normal sputtering in order that the system functions as an etching or reverse-sputtering device of the substrate, which would otherwise receive target material deposited thereon during sputtering. In preferred embodiments, thin titanium sheet materials should endure temperature annealing and rolling operations to meet desired physical characteristics.

Impurities such as carbon, oxygen and iron have recently been analysed in the titanium surface that when reduced can achieve successful deposition of the initial metal layer. In this regard, it has been discovered that the use of reverse sputter etching can reduce the surface impurities to prepare the surface for metal deposition.

Proper sputter etching time and temperature intervals were tested from reverse sputtered samples. Auger analysis techniques confirmed the optimum etch parameters. Preferably, immediately following the substrate etch, the initial metal layer is deposited by physical vacuum deposition (e.g., sputtering).

In some embodiments, the initial metal layer is deposited by PVD to form an intermixed layer of titanium and tungsten. This intermixed layer includes regions of different compositions of titanium and tungsten. In some embodiments, titanium implantation is employed while in other embodiments other materials can be used, such as, e.g., in some embodiments titanium-tungsten implantation can be employed. In preferred embodiments, nickel and gold deposits (e.g., of about 100 microinches in some illustrative embodiments) are deposited by physical vacuum deposition after, e.g., a titanium-tungsten deposition.

In some preferred applications, the metallization process used on a first side of the foil is repeated for a second side of the foil using similar PVD reverse sputter etch and metal deposition processes.

In some embodiments, foils created can meet appropriate inspection standards, such as, e.g., the same inspection standards required for electrodeposited gold process, ASTM B488-01 discussed above, including, e.g., adhesion bend testing.

In some preferred embodiments, a physical vacuum deposition process can be utilized that includes at least some, preferably all, of the following steps:
1. Cleaning the titanium foil using aqueous and/or non-aqueous methods;
2. Sputter etching one side of the foil for about, e.g., 5 to 20 minutes;
3. Sputter Depositing Titanium (such as, e.g., about 100% Titanium) or a Titanium-Tungsten alloy (e.g., about a 500 Å Titanium-Tungsten alloy [having, e.g., about a 90% Tungsten/10% Titanium]);
4. Sputter Depositing a low stress nickel (such as, e.g., about 100 microinches);
5. Sputter Depositing gold (such as, e.g., about 100 microinches);
6. Reversing the foil and repeating steps 2-5.

In some preferred embodiments, a physical vacuum deposition process can be utilized that includes at least some, preferably all, of the following steps:
1. Clean titanium foil using aqueous or non-aqueous method;
2. Magnetron sputter etch one side of foil for 5 to 20 minutes at about 400 watts and at about a vacuum of 2×10−6 Torr, or less, and at a temperature of less than about 250 C;
3. Magnetron sputter deposit 500 Å Titanium-Tungsten alloy (90% Tungsten/10% Titanium), or 100% Titanium at a process temperature of less than about 250 C;
4. Magnetron sputter deposit 100 microinches of low stress nickel at a process temperature of less than about 250 C;
5. Magnetron sputter deposit 100 microinches of gold at a process temperature of less than about 250 C;
6. Reverse panel and repeat process (steps 2-5)

In addition to that described above, aspects of the present invention can be employed in a variety of other environments, such as, e.g., in military and non-military environments. In some illustrative examples, aspects can be employed in wiring boards of fighter planes and/or the like. In other illustrative examples, aspects may be employed in various commercial and/or non-commercial computers. Among other things, aspects of the invention could be helpful as an assembly aid coating for military and/or commercial electronic assemblies to provide reduced line widths on printed circuit cards or the like for increased circuit densities. In addition, some embodiments could be employed in various contexts to help mask type coating for apparatus and equipment that needs to contact molten solder.

In addition, some embodiments could be employed in commercial underwater communications devices, such as, e.g., “sonar warning systems.”

In addition, some embodiments could be employed in heat reflecting coatings for non-metallic materials, such as, e.g., automotive glass and/or other glass and/or various other building materials.

In addition, some embodiments can achieve—when desired—one or more of the following technical results:
low cost;
enhanced safety;
controlled finish;
corrosion protection; and/or
low cost manufacturing of imbedded foils.

In addition, some embodiments can achieve—when desired—one or more of the above technical results using:
novel manufacturing processes (e.g., capable of achieving lower costs, enhanced safety, etc.);
novel metallization processes;
thin titanium; and/or
metallization of titanium foils.

In addition, some embodiments can achieve—when desired—one or more of the following benefits:
a workable thin metal foil coating process;
low risk to operations;
a process having controlled time and temperature;
long life (e.g., 12 or more years of life underwater);
enhanced water proofing (e.g., water proofing underwater transducers for 12 or more years).

### Preferred Embodiments

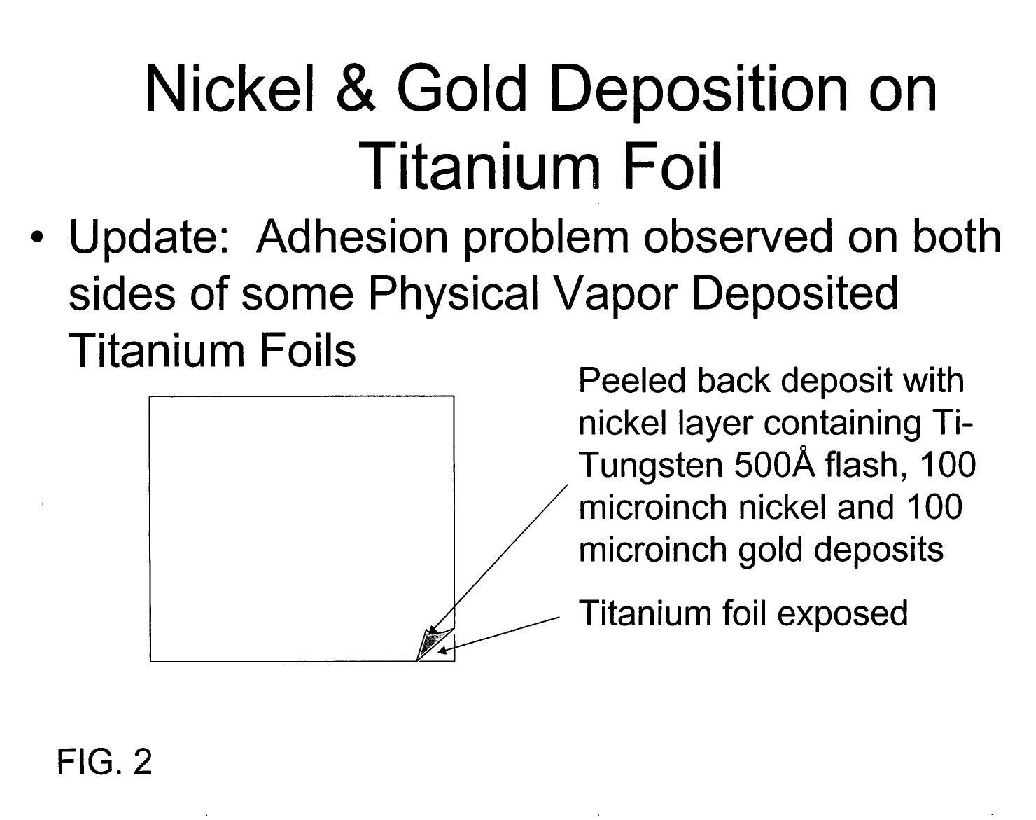

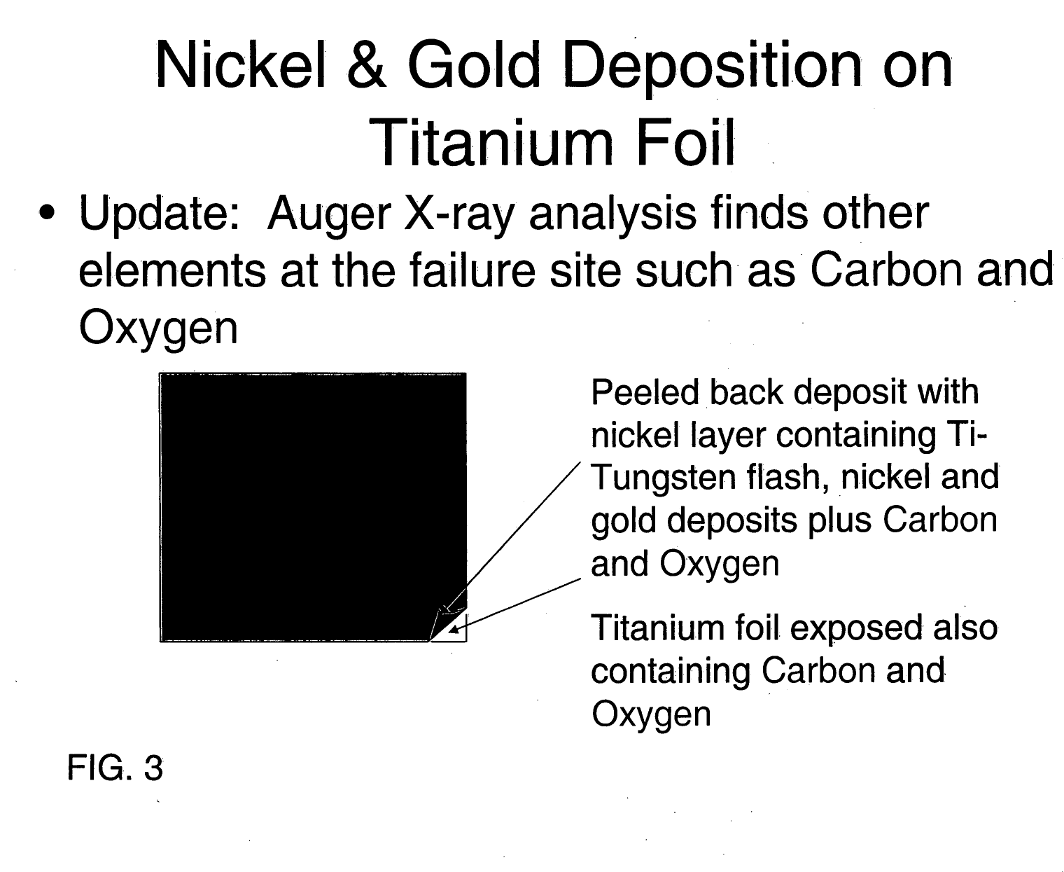

Preferred embodiments can overcome otherwise present nickel and gold adhesion problems. In this regard, bend testing of some prior physical vacuum deposited (PVD) foils revealed loss of adhesion between the Ti base metal and TiW flash deposit. See FIG. 2. For instance, an X-ray analysis of the coatings and interface by Auger reported Carbon & Oxygen in the TiW flash and Ti foil. See FIG. 3.

In some preferred embodiments, in order to improve foil deposit adhesion, one or more of the following techniques may be employed:
Adding sputter etching before coating the Ti foil;
Using improved Ti foil cleaning processes;
Adding chemical milling before coating the Ti foil;
Using Ti foil that is easier to PVD coat;
Adding Ti flash instead of TiW flash;
Using different Ti:W %; and/or
Using PVD contact straps that are constructed with high purity aluminum that has been anodized.

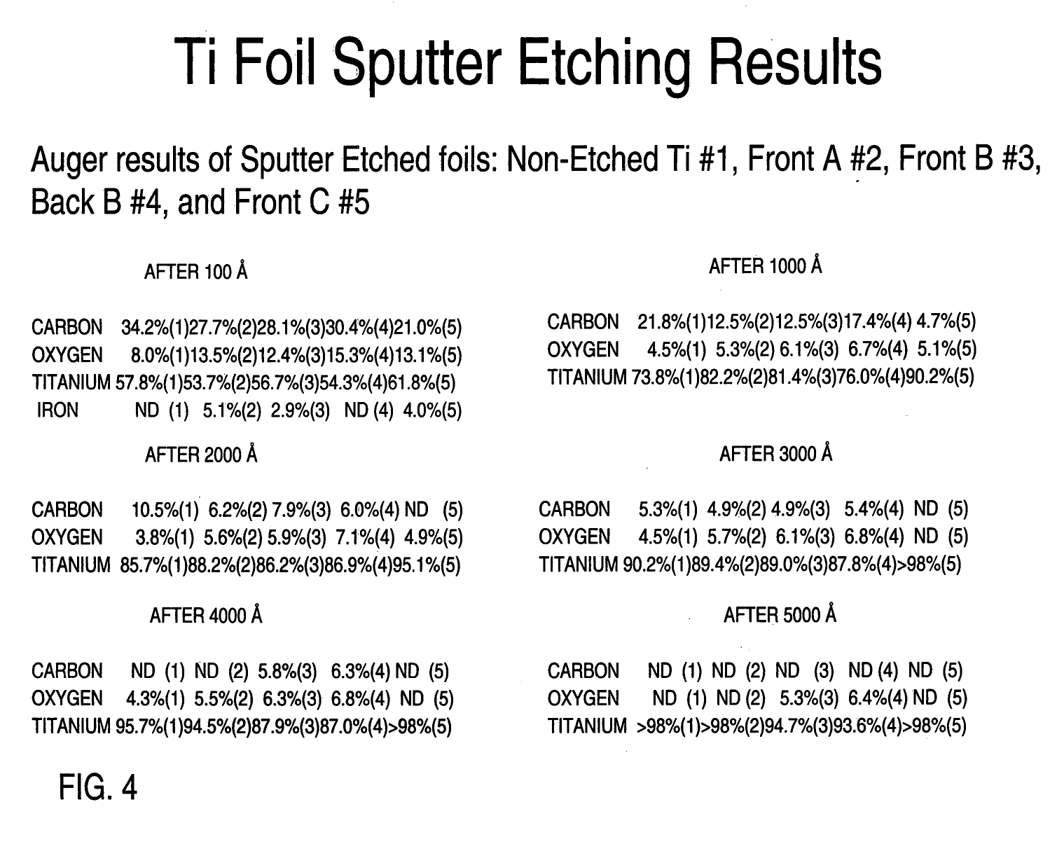

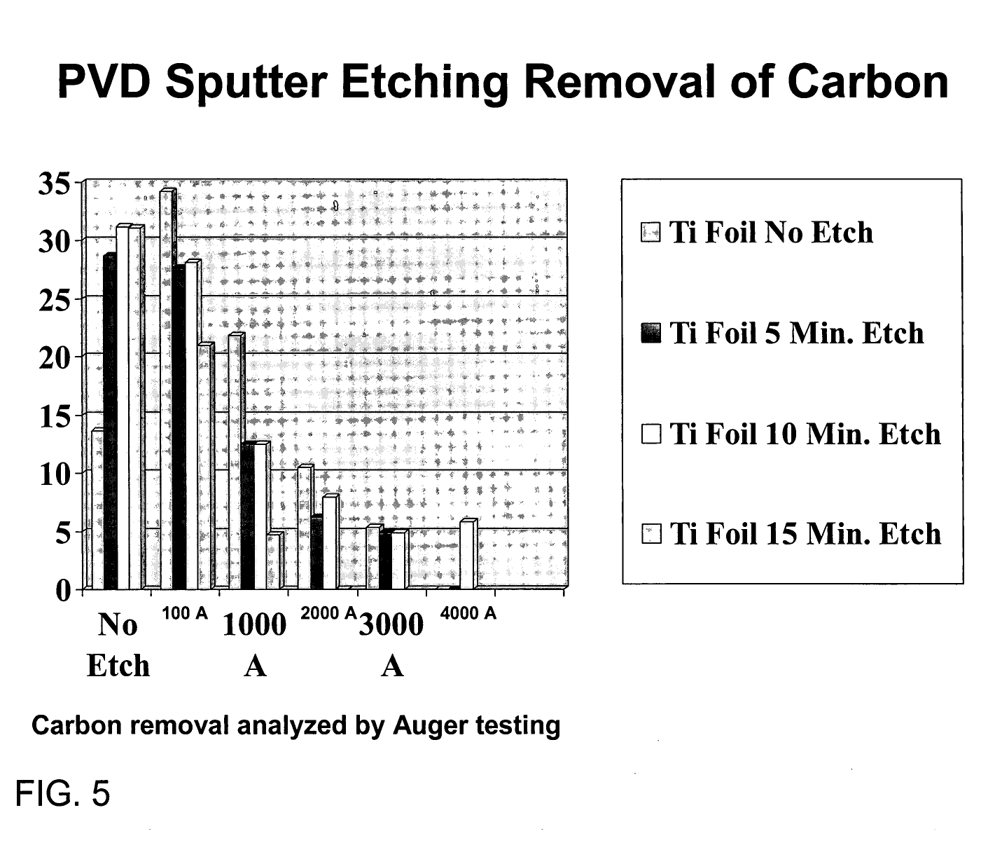

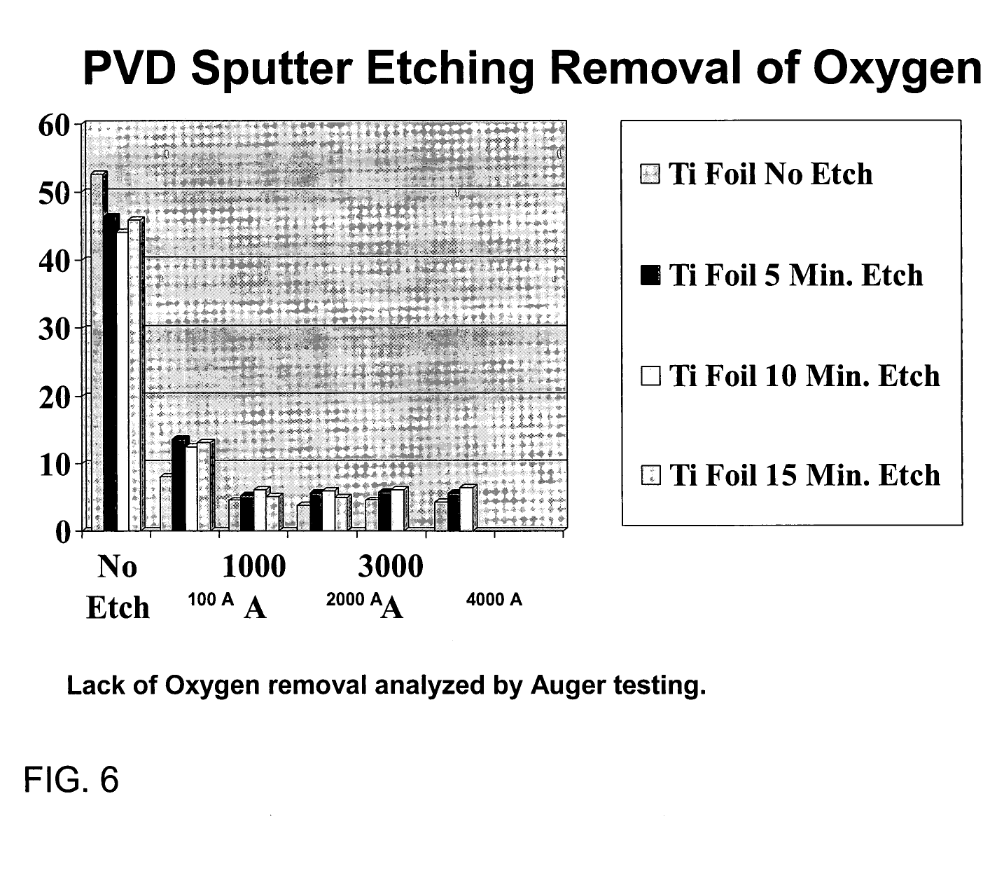

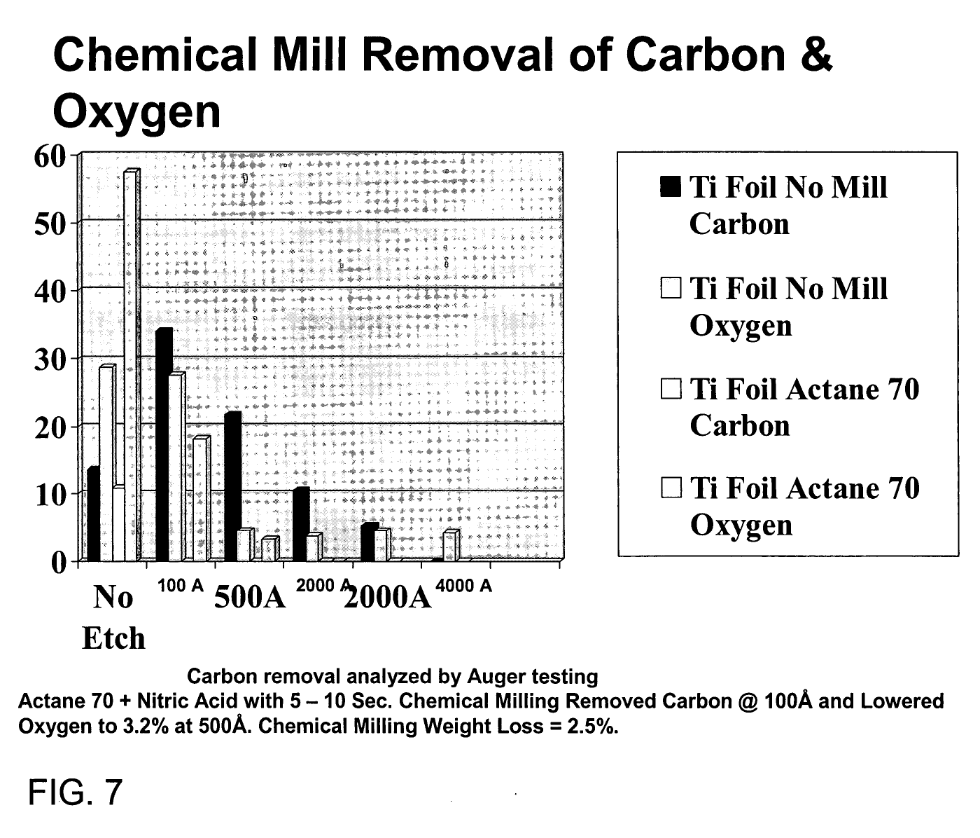

With respect to sputter etching, in some illustrative examples, sputter etching at 5, 10 and 15 minutes was tested on one or two sides of three items A, B and C, with the results shown in FIG. 4 (with the following five samples): #1—No Etching; #2—Front A 5 Minute Etch; #3—Front B 10 Minute Etch; #4—Front B Reverse Side—No Etch; #5—Front C 15 Minute Etch.

With respect to the sputter etching times selected, in preferred embodiments, the time should be sufficient to clean, but not so long as to result in surface roughing or other surface problems. For instance, in preferred applications, a smooth surface is preferably maintained. In some embodiments, the time interval can be determined based upon experimentation.

With respect to chemical milling, the following two illustrative chemical milling tests have been tested: #1) ACTANE 70 & NITRIC ACID; and #2) HYDROFLUORIC/NITRIC ACID. In these chemical milling examples, all of the carbon was removed at 100 Å and most of the oxygen was removed at 500 Å.

Results of the physical and auger testing offered a closer look at the test data. Auger testing does, however, present percentage values that are not absolute but relative to the detectable elements. Limits of detection are about 0.5%. It should also be appreciated that Auger sputtered depths are approximations based on the depth of profiling into silicon dioxide. Percentages of elements are quantitative for a particular layer, or layers of molecules, yet cannot offer the exact percentage of a particular element in the 1 mil thick foil.

Broad Scope of the Invention

While illustrative embodiments of the invention have been described herein, the present invention is not limited to the various preferred embodiments described herein, but includes any and all embodiments having modifications, omissions, combinations (e.g., of aspects across various embodiments), adaptations and/or alterations as would be appreciated by those in the art based on the present disclosure. The limitations in the claims are to be interpreted broadly based the language employed in the claims and not limited to examples described in the present specification or during the prosecution of the application, which examples are to be construed as non-exclusive. For example, in the present disclosure, the term “preferably” is non-exclusive and means “preferably, but not limited to.” Means-plus-function or step-plus-function limitations will only be employed where for a specific claim limitation all of the following conditions are present in that limitation: a) “means for” or “step for” is expressly recited; b) a corresponding function is expressly recited; and c) structure, material or acts that support that structure or step are not recited.

1. A method for nickel and gold deposition onto double-sided titanium foil, comprising: immersion cleaning and physical vacuum deposition of nickel and gold onto a double-sided titanium foil without introducing nickel and gold deposit stresses.

2. A method for nickel and gold deposition onto double-sided titanium foil, comprising: immersion cleaning and physical vacuum deposition of nickel and gold onto a double-sided titanium foil in a manner to withstand environmental conditions for at least twelve years without coating failure.

3. A method for reducing impurity levels on titanium foil surfaces, comprising: reverse sputter etching to reduce the impurity levels on titanium foil surfaces prior to deposition.

4. A physical vacuum deposition process for titanium foil, comprising: providing a Titanium or Titanium-Tungsten initial metal implantation.

5. A physical vacuum deposition process for titanium foil comprising:
a) sputter etching one side of the titanium foil for about 5 to 20 minutes;
b) sputter depositing Titanium or a Titanium-Tungsten alloy;
c) sputter depositing a low stress nickel;
d) sputter depositing gold;
e) reversing the foil and repeating steps a) to d).

6. A physical vacuum deposition process for titanium foil, comprising:
a) sputter etching one side of the titanium foil for a predetermined time period;
b) sputter depositing at least one of Titanium or a Titanium-Tungsten alloy, nickel and gold;
c) reversing the titanium foil and repeating steps a) to b).

7. A method for protecting an underwater transducer, comprising: surrounding the transducer with a thin metal foil.

8. The method of claim 7, wherein said thin metal foil is a titanium foil.

9. The method of claim 8, wherein said titanium foil is a double-sided titanium foil with nickel and gold deposition.

10. The method of claim 7, further including surrounding the thin metal foil with an elastomeric boot.

11. The method of claim 7, wherein said transducer is a sound transducer.

12. An assembly for the protection of an underwater transducer, comprising: a thin metal foil for surrounding the transducer.

13. The assembly of claim 12, wherein said thin metal foil is a titanium foil.

14. The assembly of claim 13, wherein said titanium foil is a double-sided titanium foil with nickel and gold deposition.

15. The assembly of claim 12, further including an elastomeric boot for surrounding the thin metal foil.

16. The assembly of claim 12, wherein said transducer is a sound transducer.
